(19) United States
(12) Patent Application Publication
(10) Pub. No.: US 2018/0132356 A1
(43) Pub. Date: May 10, 2018

(54) METHOD FOR MANUFACTURING CAPACITOR BUILT-IN SUBSTRATE

(71) Applicant: Murata Manufacturing Co., Ltd., Nagaokakyo-shi (JP)

(72) Inventors: TATSUYA FUNAKI, Nagaokakyo-shi (JP); Noriyuki Inoue, Nagaokakyo-shi (JP)

(21) Appl. No.: 15/846,492

(22) Filed: Dec. 19, 2017

Related U.S. Application Data
(63) Continuation of application No. PCT/JP2016/069533, filed on Jun. 30, 2016.

(30) Foreign Application Priority Data
Aug. 11, 2015 (JP) 2015-159091

(51) Int. Cl. H05K 1/18; H01G 4/005; H01G 4/248

(52) U.S. Cl. CPC H05K 1/185; H01G 4/005; H01G 4/248; H05K 2201/10015; H05K 3/32; H05K 2201/10537; H05K 2201/10553; H05K 2201/1056; H05K 2201/10522

(57) ABSTRACT

A method for manufacturing a capacitor built-in substrate includes: preparing a capacitor built-in core insulating film and laminating a respective buildup layer to each of opposed main surfaces of the capacitor built-in core insulating film. The capacitor built-in core insulating film includes a first and second metal layers, an insulating layer and a capacitor. The first and second metal layers are disposed so as to face each other with the insulating layer interposed therebetween. The capacitor is disposed so as to extend through the insulating layer with one capacitor electrode being electrically connected to the first metal layer and the other capacitor electrode being electrically connected to the second metal layer.

### CROSS REFERENCE TO RELATED APPLICATION

The present application is a continuation of International application No. PCT/JP2016/069533, filed Jun. 3, 2016, which claims priority to Japanese Patent Application No. 2015-159091, filed Aug. 11, 2015, the entire contents of each of which are incorporated herein by reference.

### TECHNICAL FIELD

The present invention relates to a method for manufacturing a capacitor built-in substrate.

### BACKGROUND ART

In recent years, miniaturization and complexation of electronic components have been required along with an increase in mounting density of electronic devices. However, mounting of an electronic component on a substrate is generally performed by mounting the electronic component on a surface of the substrate, and in such a mounting method, there is a limit to high-density mounting because the area of the top of a substrate is limited.

In view of the above-mentioned problem, a technique for mounting a larger number of electronic components on a substrate by building electronic components in the substrate is known. For example, Tadashi Shiroishi, et al. “Development of Practical Application of Component Built-In Substrate”, Matsushita Technical Journal, Vol. 54, No. 1, PP. 8-12, 2008 suggests that an upper circuit board and a lower circuit board are provided, electronic components such as semiconductor elements are mounted on the surfaces of the upper circuit board and the lower circuit board, the resulting component-mounting surfaces of the upper circuit board and the lower circuit board are made to face each other, and these boards are bonded to each other by hot pressing with a composite material disposed therebetween, so that a built-in substrate is manufactured.

The method for manufacturing a built-in substrate in the foregoing publication includes the steps of:

(1) preparing an upper circuit board and a lower circuit board;

(2) mounting electronic components on the upper circuit board and the lower circuit board by surface mounting technique; and

(3) thermocompression-bonding the upper and lower electronic component-mounted circuit boards and a composite material in layers. In the above-mentioned method, it is necessary to mount an electronic component on each of two circuit boards for preparing one built-in substrate. That is, it is necessary to repeat the step (1) and the step (2) twice, leading to complication of the steps. Further, the step (1) and the step (3) are substrate manufacturing steps, which are well linked to each other, but the step (2) between the steps (1) and (3) is an electronic component mounting step, which involves equipment utterly different from that in the substrate manufacturing steps, and therefore linking as a whole manufacturing method is deteriorated. Therefore, in the method described in the foregoing publication, the time required for manufacturing is prolonged, and the cost required for manufacturing is increased.

An object of the present invention is to provide a convenient method for manufacturing a capacitor built-in substrate with well-linked manufacturing steps.

### BRIEF DESCRIPTION OF THE INVENTION

The inventors have extensively conducted studies for solving the above-mentioned problems and have discovered that when an insulating film with a capacitor built therein is manufactured separately and subsequently laminated to a circuit board, rather than surface-mounting a capacitor on each circuit board, a capacitor built-in substrate can be prepared conveniently and with well linked manufacturing steps.

According to a first aspect of the present invention, there is provided a method for manufacturing a capacitor built-in substrate, the method including the steps of:

preparing a capacitor built-in core insulating film; and

laminating a buildup layer to each of both main surfaces of the capacitor built-in core insulating film,

wherein

the capacitor built-in core insulating film includes a first metal layer and a second metal layer; an insulating layer; and a capacitor,

the first metal layer and the second metal layer are disposed so as to face each other with the insulating layer interposed between the first metal layer and the second metal layer, and

the capacitor is disposed so as to extend through the insulating layer, with one capacitor electrode being electrically connected to the first metal layer and the other capacitor electrode being electrically connected to the second metal layer.

According to a second aspect of the present invention, there is provided a method for manufacturing a capacitor built-in substrate, the method including the steps of:

preparing a capacitor built-in interlayer insulating film; and

laminating the capacitor built-in interlayer insulating film as a buildup layer on a core insulating film,

wherein

the capacitor built-in interlayer insulating film includes an insulating layer; and a capacitor, and

the capacitor is disposed so as to extend through the insulating layer with a capacitor electrode being exposed from each of both main surfaces of the insulating layer.

According to a third aspect of the present invention, there is provided a capacitor built-in core insulating film including a first metal layer and a second metal layer; an insulating layer; and a capacitor,

wherein

the first metal layer and the second metal layer are disposed so as to face each other with the insulating layer interposed between the first metal layer and the second metal layer, and

the capacitor is disposed so as to extend through the insulating layer, with one capacitor electrode being electrically connected to the first metal layer and the other capacitor electrode being electrically connected to the second metal layer.

According to a fourth aspect of the present invention, there is provided a film product including a protecting film or a support film on one or both of main surfaces of the capacitor built-in core insulating film.

According to a fifth aspect of the present invention, there is provided a capacitor built-in interlayer insulating film including an insulating layer; and a capacitor,

wherein the capacitor is disposed so as to extend through the insulating layer with a capacitor electrode being exposed from each of both main surfaces of the insulating layer.

According to a sixth aspect of the present invention, there is provided a film product including a protecting film or a support film on one or both of main surfaces of the capacitor built-in interlayer insulating film.

According to the present invention, a capacitor built-in substrate can be conveniently and efficiently manufactured by preparing a capacitor built-in insulating film, and bonding the capacitor built-in insulating film to a circuit board in manufacturing of a capacitor built-in substrate.

### BRIEF EXPLANATION OF DRAWINGS

FIG. 1 is a schematic plan view of a capacitor built-in core insulating film 11 in one embodiment of the present invention.

FIG. 2 is a schematic sectional view taken along line x-x of the capacitor built-in core insulating film 11 shown in FIG. 1.

FIG. 3 is a schematic perspective view of a capacitor 51 for use in the present invention.

FIG. 4 is a view schematically showing an enlarged view of a high-porosity section of the capacitor 51 in FIG. 3.

FIG. 5 is a schematic sectional view of a capacitor 71 for use in the present invention.

FIG. 6 is a view schematically showing an enlarged view of a high-porosity section of the capacitor 71 in FIG. 5.

FIG. 7 is a process flow diagram including steps (a)-(f) showing a method for manufacturing a capacitor built-in core insulating film.

FIG. 8 is a process flow diagram including stages (a)-(f) showing another method for manufacturing a capacitor built-in core insulating film.

FIG. 9 is a process flow diagram including steps (a)-(g) showing yet another method for manufacturing a capacitor built-in core insulating film.

FIG. 10 is a process flow diagram including steps (a)-(c) showing another method for manufacturing a capacitor built-in substrate of the present invention including a capacitor built-in core insulating film.

FIG. 11 is a schematic plan view of a capacitor built-in interlayer insulating film 41 in one embodiment of the present invention.

FIG. 12 is a schematic sectional view taken along line x-x of the capacitor built-in interlayer insulating film 41 shown in FIG. 10.

FIG. 13 is a process flow diagram including steps (a)-(d) showing another method for manufacturing a capacitor built-in interlayer insulating film.

FIG. 14 is a process flow diagram including steps (a)-(d) showing another method for manufacturing a capacitor built-in substrate of the present invention including a capacitor built-in interlayer insulating film.

### DETAILED DESCRIPTION OF THE PREFERRED EMBODIMENTS

Hereinafter, a method for manufacturing a capacitor built-in substrate of the present invention will be described in detail with reference to the drawings. However, the shape, the disposition and the like of constituent elements of the capacitor built-in substrate or the like of this embodiment are not limited to examples shown in the drawings.

A first manufacturing method of the present invention includes:

preparing a capacitor built-in core insulating film; and

laminating a buildup layer to each of both main surfaces of the capacitor built-in core insulating film,

wherein

the capacitor built-in core insulating film includes a first metal layer and a second metal layer; an insulating layer; and a capacitor,

the first metal layer and the second metal layer are disposed so as to face each other with the insulating layer interposed between the first metal layer and the second metal layer, and

the capacitor is disposed so as to extend through the insulating layer, with one capacitor electrode being electrically connected to the first metal layer and the other capacitor electrode being electrically connected to the second metal layer.

First, the capacitor built-in core insulating film will be described.

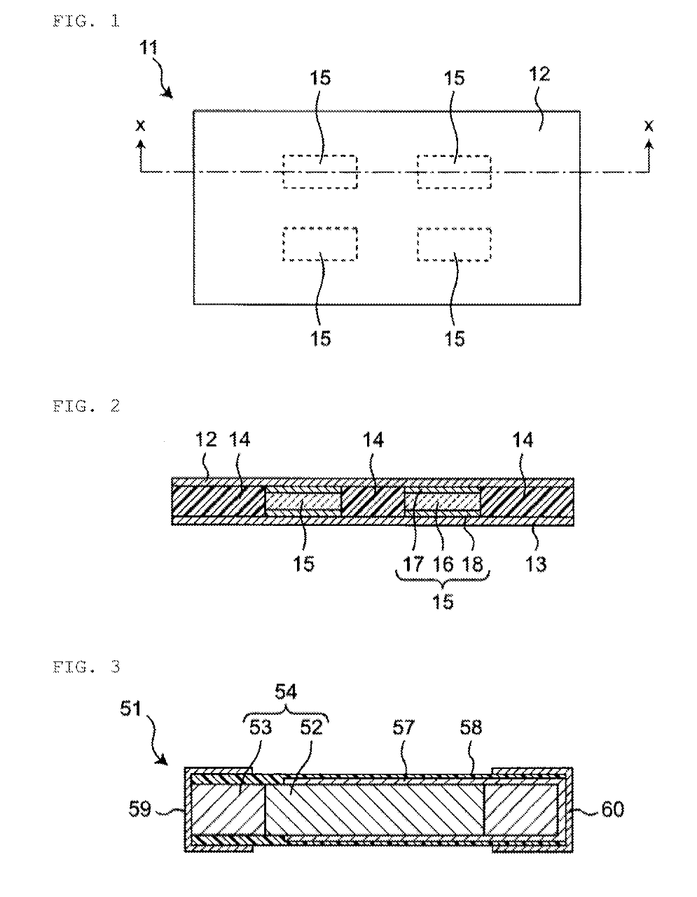

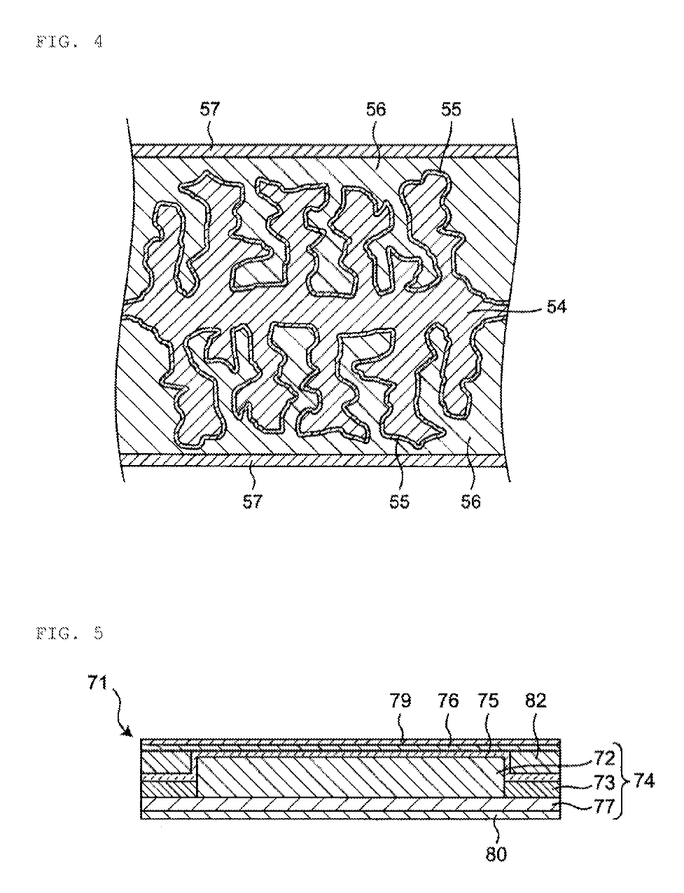

As shown in FIGS. 1 and 2, a capacitor built-in core insulating film 11 for use in this embodiment schematically includes a first metal layer 12 and a second metal layer 13; an insulating layer 14; and a capacitor 15. The first metal layer 12 and the second metal layer 13 are disposed so as to face each other with the insulating layer 14 interposed therebetween. The capacitor 15 including a dielectric layer 16, a first capacitor electrode 17 and a second capacitor electrode 18 is disposed so as to extend through the insulating layer 14, with one capacitor electrode (i.e., first capacitor electrode 17) being electrically connected to the first metal layer 12 and the other capacitor electrode (i.e., second capacitor electrode 18) being electrically connected to the second metal layer 13.

The first metal layer 12 and the second metal layer 13 serve to electrically connect the capacitor 15 and a circuit board bonded to the capacitor built-in core insulating film 11. The first and second metal layers 12 and 13 may cover the whole surface of the insulating layer 14 or only a part of the insulating layer 14. The metal layers 12 and 13 preferably serve as wiring layers.

The materials that form the first metal layer 12 and the second metal layer 13 are not particularly limited, and examples thereof include Au, Pb, Pd, Ag, Sn, Ni and Cu. The materials that form the first metal layer 12 and the second metal layer 13 may be the same or different. The materials that form the first metal layer 12 and the second metal layer 13 are each preferably Cu.

The thickness of each of the first metal layer 12 and the second metal layer 13 is not particularly limited, and for example, it may be 1 μm or more and 100 μm or less, preferably 5 μm or more and 50 μm or less, for example, 10 μm or more and 30 μm or less.

The material that forms the insulating layer 14 is not particularly limited as long as it has insulation quality, and examples thereof include epoxy resins, polyimide-based resin, fluorine-based resins, various glass materials and ceramic materials. When the capacitor built-in core insulating film and the circuit board are thermocompression-bonded to each other later, a resin having heat resistance is preferable. These insulating materials may contain a filler such as an Si filler.

The thickness of the insulating layer 14 can be appropriately set according to the size of the built-in capacitor.

The capacitor 15 is not particularly limited, and various types of capacitors can be used.

In a preferred aspect, the capacitor is a capacitor including a conductive porous base material, a dielectric layer situated on the conductive porous base material, and an upper electrode situated on the dielectric layer. Such a capacitor is advantageous in that the base material has a large surface area, and thus a large electrostatic capacitance can be obtained.

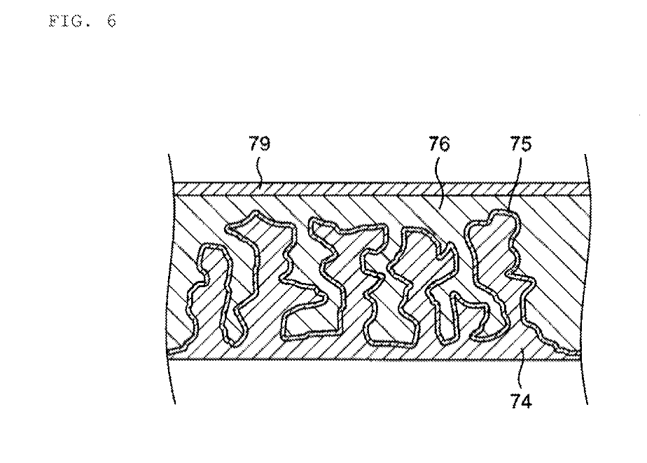

In one aspect, the capacitor may be a capacitor 51 shown in FIGS. 3 and 4. FIG. 3 shows a schematic sectional view of the capacitor 51 (for simplification, a dielectric layer 55 and an upper electrode 56 are not shown), and FIG. 4 schematically shows an enlarged view of a high-porosity section of the capacitor 51. As shown in FIGS. 3 and 4, the capacitor 51 has a substantially rectangular-solid shape. Schematically, the capacitor 51 includes a conductive porous base material 54 having a high-porosity section 52 at the central part and a low-porosity section 53 at the side part, a dielectric layer 55 formed on the conductive porous base material 54, an upper electrode 56 formed on the dielectric layer 55, a wiring electrode 57 formed thereon so as to be electrically connected to the upper electrode 56, and a protecting layer 58 moreover formed thereon. On the side surfaces of the conductive porous base material 54, a first capacitor electrode 59 and a second capacitor electrode 60 are provided so as to face each other. The first capacitor electrode 59 is electrically connected to the conductive porous base material 54, and the second capacitor electrode 60 is electrically connected to the upper electrode 56 through the wiring electrode 57. The upper electrode 56 and the high-porosity section 52 of the conductive porous base material 54 face each other with the dielectric layer 55 interposed therebetween. When an electric current is fed to the conductive porous base material 54 and the upper electrode 56 through the first capacitor electrode 59 and the second capacitor electrode 60, electric charges can be accumulated in the dielectric layer 55.

As shown in FIG. 4, such a capacitor may have porous sections (high-porosity sections) on both main surfaces of the conductive porous base material, so that a larger electrostatic capacitance can be obtained.

In another aspect, the capacitor may be a capacitor 71 shown in FIGS. 5 and 6. FIG. 5 shows a schematic sectional view of the capacitor 71 (for simplification, pores are not shown), and FIG. 6 schematically shows an enlarged view of a high-porosity section of the capacitor 71. As shown in FIGS. 5 and 6, the capacitor 71 has a substantially rectangular-solid shape, and schematically, the capacitor 71 includes a conductive porous base material 74, a dielectric layer 75 formed on the conductive porous base material 74, and an upper electrode 76 formed on the dielectric layer 75. The conductive porous base material 74 has a high-porosity section 72 having a relatively high porosity and a low-porosity section 73 having a relatively low porosity on one main surface side. The high-porosity section 72 is situated at the central part of the first main surface (main surface on the upper side in the drawing) of the conductive porous base material 74, and the low-porosity section 73 is situated on the periphery of the high-porosity section 72. That is, the low-porosity section 73 surrounds the high-porosity section 72. The high-porosity section 72 has a porous structure, i.e., the high-porosity section is a porous section. In addition, the conductive porous base material 74 has a support section 77 on the other main surface side (second main surface; main surface on the lower side in the drawing). That is, the high-porosity section 72 and the low-porosity section 73 form a first main surface of the conductive porous base material 74, and the support section 77 forms a second main surface of the conductive porous base material 74. In FIG. 5, the first main surface is the upper surface of the conductive porous base material 74, and the second main surface is the lower surface of the conductive porous base material 74. At the end part of the capacitor 71, an insulating section 82 exists between the dielectric layer 75 and the upper electrode 76. The capacitor 71 includes a first capacitor electrode 79 on the upper electrode 76, and a second capacitor electrode 80 on the main surface of the conductive porous base material 74 on the support section 77 side. In the capacitor 71, the first capacitor electrode 79 and the upper electrode 76 are electrically connected to each other, and the second capacitor electrode 80 is electrically connected to the second main surface of the conductive porous base material 74. The upper electrode 76 and the high-porosity section 72 of the conductive porous base material 74 face each other with the dielectric layer 75 interposed therebetween, and when an electric current is fed to the upper electrode 76 and the conductive porous base material 74, electric charges can be accumulated in the dielectric layer 75.

The capacitor 71 includes a capacitor electrode on each of the upper main surface and the lower main surface of the capacitor, and therefore can be disposed in the same direction as the direction of the film (i.e., the main surface of the film and the main surface of the capacitor can be disposed in parallel) when the capacitor 71 is built in the film. This is advantageous from the viewpoint of lowering the height.

The conductive porous base material has a porous structure, and the material and the configuration thereof are not limited as long as the surface is electrically conductive. Examples of the conductive porous base material include porous metal base materials, and base materials with a conductive layer formed on the surface of a porous silica material, a porous carbon material or a porous ceramic sintered body. In a preferred embodiment, the conductive porous base material is a porous metal base material.

Examples of the metal that forms the porous metal base material include metals such as aluminum, tantalum, nickel, copper, titanium, niobium and iron, and alloys such as stainless steel and duralumin. Preferably, the porous metal base material is an aluminum porous base material.

The conductive porous base material may have a low-porosity section and a support section in addition to a high-porosity section (i.e., porous section).

In this specification, the “porosity” refers to a ratio of voids to the conductive porous base material. The porosity can be measured in the following manner. The voids of the porous section can be finally filled with the dielectric layer, the upper electrode and the like in the process for preparing a capacitor, but the above-mentioned “porosity” is calculated with the filled portions considered as voids without giving consideration to such substances filled into the voids.

First, the porous metal base material is processed by a FIB (focused ion beam) micro-sampling method to obtain a thin piece sample having a thickness of 60 nm or less. A predetermined region (3 μm×3 μm) of the thin piece sample is measured by STEM (scanning transmission electron microscope)−EDS (energy dispersive X-ray spectrometry) mapping analysis. In the mapping measurement field of view, an area of a region where the metal of the porous metal base material exists is determined. A porosity can be calculated from the following equation. This measurement is performed at any three spots, and an average of the measured values is defined as a porosity.

Porosity (%)=((measurement area−area of region where metal of base material exists)/measured area)×100

In this specification, the “high-porosity section” means a section having a porosity higher than that of each of the support section and the low-porosity section of the conductive porous base material.

The high-porosity section has a porous structure. The high-porosity section having a porous structure increases the specific surface area of the conductive porous base material, and further increases the electrostatic capacitance of the capacitor.

The porosity of the high-porosity section may be preferably 20% or more, more preferably 30% or more, still more preferably 35% or more for increasing the specific surface area and increasing the electrostatic capacitance of the capacitor. For securing mechanical strength, the porosity is preferably 90% or less, and more preferably 80% or less.

The surface enlargement ratio of the high-porosity section is not particularly limited, but is preferably 30 times or more and 10,000 times or less, more preferably 50 times or more and 5,000 times or less, for example 200 times or more and 600 times or less. Here, the surface enlargement ratio means a surface area per unit projected area. The surface area per unit projected area can be determined from the adsorption amount of nitrogen at a liquid nitrogen temperature using a BET specific surface area measuring apparatus.

In addition, the surface enlargement ratio can also be determined by the following method. A STEM (scanning transmission electron microscope) image of a cross-section (cross-section obtained by cutting the sample in the thickness direction) of the sample is taken along the whole thickness (height) T with a width X (a plurality of images may be connected if the cross-section cannot be photographed at once). The total path length L (the total length of the pore surface) of the obtained pore surface of the cross-section having a width X and a height T. Here, the total path length of the pore surface in a regular quadrangular prism region having as one side surface the cross-section having a width X and a height T and having the porous base material surface as one bottom surface is LX. In addition, the bottom area of the regular quadrangular prism is X2. Therefore, the surface enlargement ratio can be determined as LX/X2=L/X.

In this specification, the “low-porosity section” means a section having a low porosity as compared with the high-porosity section. Preferably, the porosity of the low-porosity section is lower than the porosity of the high-porosity section, and is not less than the porosity of the support section.

The porosity of the low-porosity section is preferably 20% or less, more preferably 10% or less. In addition, the low-porosity section may have a porosity of 0%. That is, the low-porosity section may have a porous structure, or may have no porous structure. The lower the porosity of the low-porosity section, the higher the mechanical strength of the capacitor.

The low-porosity section is not an essential constituent element in the present invention, and may be absent.

In the present invention, the position at which the high-porosity section and the low-porosity section exist, the number of high-porosity sections and low-porosity sections that are provided, the size and shape of the high-porosity section and the low-porosity section, the ratio of both the high-porosity section and the low-porosity section and so on in the conductive porous base material are not particularly limited. For example, one main surface of the conductive porous base material may include only the high-porosity section. By adjusting the ratio of the high-porosity section and the low-porosity section, the electrostatic capacitance of the capacitor can be controlled.

The thickness of the high-porosity section is not particularly limited, and can be appropriately selected according to the purpose, and for example, it may be 10 or more, preferably 30 μm or more, and preferably 1000 μm or less, more preferably 300 μm or less, still more preferably 50 μm or less.

The porosity of the support section of the conductive porous base material is preferably smaller for exhibiting a function as the support, and specifically it is preferably 10% or less. More preferably, the support section has substantially no voids.

The thickness of the support section is not particularly limited, but it is preferably 10 μm or more, and may be, for example, 30 μm or more, 50 μm or more, or 100 μm or more for increasing the mechanical strength of the capacitor. For reducing the height of the capacitor, the thickness of the support section is preferably 1000 μm or less, and may be, for example, 500 μm or less, or 100 μm or less.

The thickness of the conductive porous base material is not particularly limited, and can be appropriately selected according to the purpose, and it may be, for example, 20 μm or more, preferably 30 μm or more, and, for example, 1000 μm or less, preferably 100 μm or less, more preferably 70 μm or less, still more preferably 50 or less.

The method for manufacturing the conductive porous base material is not particularly limited. For example, the conductive porous base material can be manufactured by treating an appropriate metal material with a method for forming a porous structure, a method for crushing (filling) a porous structure, a method for removing a porous structure section, or a method for combining these methods.

The metal material for manufacturing the conductive porous base material may be a porous metal material (e.g., etched foil), a metal material having no porous structure (e.g., metal foil), or a combination of these materials. The method for combining the materials is not particularly limited, and examples thereof include methods in which the materials are bonded by welding, a conductive adhesive or the like.

The method for forming a porous structure is not particularly limited, but an etching treatment, for example a direct-current or alternating-current etching treatment is preferable.

Examples of the method for crushing (filling) a porous structure include, but are not particularly limited to, a method in which pores are crushed by melting a metal by laser irradiation or the like, and a method in which pores are crushed by compression by die processing or press processing. Examples of the laser include, but are not particularly limited to, CO2 lasers, YAG lasers, excimer lasers, and all-solid pulsed lasers such femtosecond lasers, picosecond lasers and nanosecond lasers. All-solid pulsed lasers such as femtosecond lasers, picosecond lasers and nanosecond lasers are preferable because the shape and the porosity can be more precisely controlled.

Examples of the method for removing a porous structure section include, but are not particularly limited to, dicer processing and ablation processing.

In one method, the conductive porous base material can be manufactured by providing a porous metal material, and crushing (filling) pores in portions corresponding to the support section and the low-porosity section of the porous metal base material.

It is not necessary to form the support section and the low-porosity section at the same time they may be formed separately. For example, first a portion corresponding to the support section of the porous metal base material is treated to form a support section, and then a portion corresponding to the low-porosity section is treated to form a low-porosity section.

In another method, the conductive porous base material can be manufactured by forming a porous structure by treating a portion corresponding to the high-porosity section of a metal base material (e.g., metal foil) having no porous structure.

In still another method, the conductive porous base material having no low-porosity section can be manufactured by crushing pores in a portion corresponding to the support section of the porous metal material, and then removing a portion corresponding to the low-porosity section.

In the capacitor for use in the present invention, a dielectric layer is formed on the high-porosity section.

The material for forming the dielectric layer is not particularly limited as long as it has insulation quality, but it is preferably a metal oxide such as AlOx (e.g., Al2O3), SiOx (e.g., SiO2), AlTiOx, SiTiOx, HfOx, TaOx, ZrOx, HfSiOx, ZrSiOx, TiZrOx, TiZrWOx, TiOx, SrTiOx, PbTiOx, BaTiOx, BaSrTiOx, BaCaTiOx or SiAlOx; a metal nitride such as AlNx, SiNx or AlScNx; or a metal oxynitride such as AlOxNy, SiOxNy, HfSiOxNy or SiCxOyNz, and AlOx, SiOx, SiOxNy or HfSiOx is preferable. The formulae described above merely represent the constitutions of materials, and do not limit compositions. That is, x, y and z added to O and N may be any value larger than 0, and the abundance ratios of the elements including metal elements are arbitrary.

The thickness of the dielectric layer is not particularly limited, but for example, it is preferably 5 nm or more and 100 nm or less, more preferably 10 nm or more and 50 nm or less. When the thickness of the dielectric layer is 5 nm or more, insulation quality can be improved, and the leakage current can be reduced. In addition, when the thickness of the dielectric layer is 100 nm or less, a larger electrostatic capacitance can be obtained.

The dielectric layer is formed preferably by a gas phase method such as a vacuum vapor deposition method, a chemical vapor deposition (CVD) method, a sputtering method, an atomic layer deposition (ALD) method, a pulsed laser deposition (PLD) method or the like. An ALD method is more preferable because a more homogeneous and denser film can be formed even in the fine portions of pores of a porous member.

In one aspect (e.g., in the capacitor 71), an insulating section is provided at the end of the dielectric layer. By providing the insulating section, a short circuit between the upper electrode and the conductive porous base material that are provided on the insulating section can be prevented.

In the capacitor 71, the insulating section exists on the whole of the low-porosity section, but the present invention is not limited thereto, and the insulating section may exist on only a part of the low-porosity section, or may extend over the low-porosity section to the top of the high-porosity section.

In the capacitor 71, the insulating section is situated between the dielectric layer and the upper electrode, but the present invention is not limited thereto. The insulating section may be situated between the conductive porous base material and the upper electrode, and may be situated, for example, between the low-porosity section and the dielectric layer.

The material that forms the insulating section is not particularly limited as long as it has insulation quality, but when an atomic layer deposition method is used later, a resin having heat resistance is preferable. As the insulating material that forms the insulating section, various kinds of glass materials, ceramic materials, polyimide-based resins, and fluorine-based resins are preferable.

The thickness of the insulating section is not particularly limited, but for reliably preventing discharge at the end surface, the thickness of the insulating section is preferably 1 μm or more, and may be, for example, 5 μm or more, or 10 μm or more. For reducing the height of the capacitor, the thickness of the insulating section is preferably 100 μm or less, and may be, for example, 50 μm or less, or 20 μm or less.

In the capacitor for use in the present invention, the insulating section is not an essential element, and may be absent.

An upper electrode is formed on the dielectric layer.

The material that forms the upper electrode is not particularly limited as long as it has conductivity, and examples thereof include Ni, Cu, Al, W, Ti, Ag, Au, Pt, Zn, Sn, Pb, Fe, Cr, Mo, Ru, Pd, Ta, and alloys thereof such as CuNi, AuNi and AuSn; metal nitrides and metal oxynitrides such as TiN, TiAlN, TiON, TiAlON and TaN; and conductive polymers (e.g., PEDOT (poly(3,4-ethylenedioxythiophene)), polypyrrole, polyaniline), and TiN and TiON are preferable.

The thickness of the upper electrode is not particularly limited, but for example, it is preferably 3 nm or more, more preferably 10 nm or more. When the thickness of the upper electrode is 3 nm or more, the resistance of the upper electrode itself can be reduced.

The upper electrode may be formed by an ALD method. By using the ALD method, the electrostatic capacitance of the capacitor can be further increased. Alternatively, the upper electrode may be formed by a method capable of covering the dielectric layer and substantially filling pores of the porous metal base material, such as a chemical vapor deposition (CVD) method, plating, bias sputtering, a sol-gel method, or filling of conductive polymers. The upper electrode may be formed preferably by forming a conductive film on the dielectric layer by an ALD method, and filling pores with a conductive material, preferably a substance having a lower electrical resistance, from above the conductive film using other method. By adopting such a configuration, a higher electrostatic capacitance density and a lower equivalent series resistance (ESR) can be efficiently obtained.

When the upper electrode does not have sufficient conductivity as a capacitor electrode after formation of the upper electrode, an extraction electrode layer composed of Al, Cu, Ni or the like may be additionally formed on the surface of the upper electrode by a method such as sputtering, vapor deposition or plating.

In one aspect, the first capacitor electrode may be formed so as to be electrically connected to the upper electrode, and the second capacitor electrode may be formed so as to be electrically connected to the conductive porous base material.

The material that forms the capacitor electrode is not particularly limited, and examples thereof include metals such as Au, Pb, Pd, Ag, Sn, Ni and Cu, alloys, and conductive polymers. The method for forming the first capacitor electrode is not particularly limited, and for example, a method such as a CVD method, electrolytic plating, electroless plating, vapor deposition, sputtering or baking of a conductive paste can be used, and electrolytic plating, electroless plating, sputtering or the like is preferable.

The position to be provided, size and the like of the capacitor electrode are not particularly limited, and the capacitor electrode can be provided on only a part of each surface in any shape and size. In addition, the first capacitor electrode and the second capacitor electrode are not essential elements, and may be omitted. Here, the upper electrode may also serve as the first capacitor electrode, and the conductive base material may serve as the second capacitor electrode. That is, the upper electrode and the conductive porous base material may serve as a pair of electrodes. Here, the upper electrode may serve as an anode, and the conductive porous base material may serve as a cathode. Alternatively, the upper electrode may serve as a cathode, and the conductive porous base material may serve as an anode.

The capacitor 51 and the capacitor 71 have a substantially rectangular-solid shape, but the capacitor for use in the present invention is not limited thereto. The capacitor may have any shape, and for example, the planar shape of the capacitor may be a circular shape, an elliptic shape, a tetragonal shape with rounded corners, or the like.

In addition, the capacitor for use in the present invention can be subjected to various modifications.

For example, a layer for improving adhesion between layers, or a buffer layer for preventing diffusion of components between layers may be provided between the layers. In addition, a protecting layer may be provided on the side surface of the capacitor, or the like.

A method for manufacturing a capacitor built-in core insulating film will now be described.

In one aspect, a capacitor in-built core insulating film 11 can be manufactured in the following manner:

a support film 22 having a surface coated with an adhesive material 21 is provided,

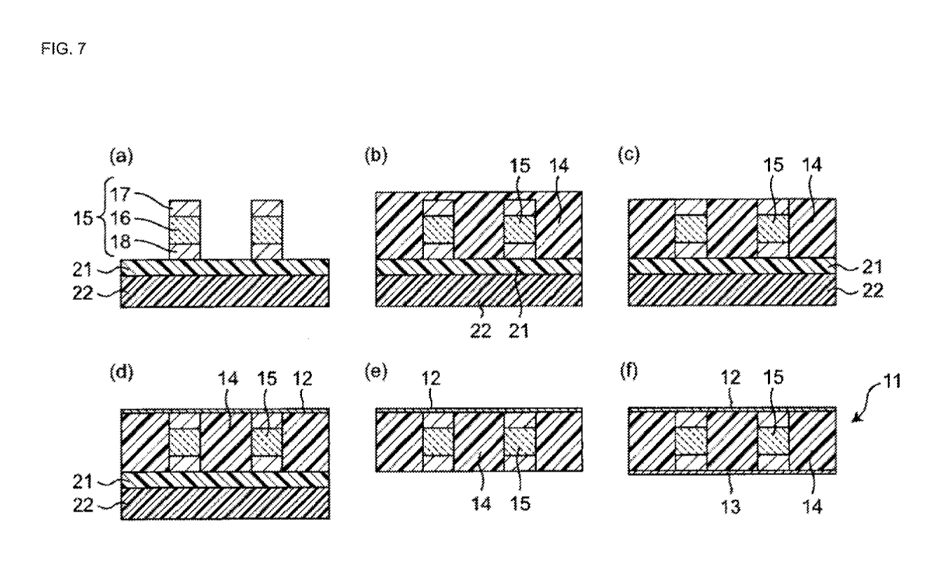

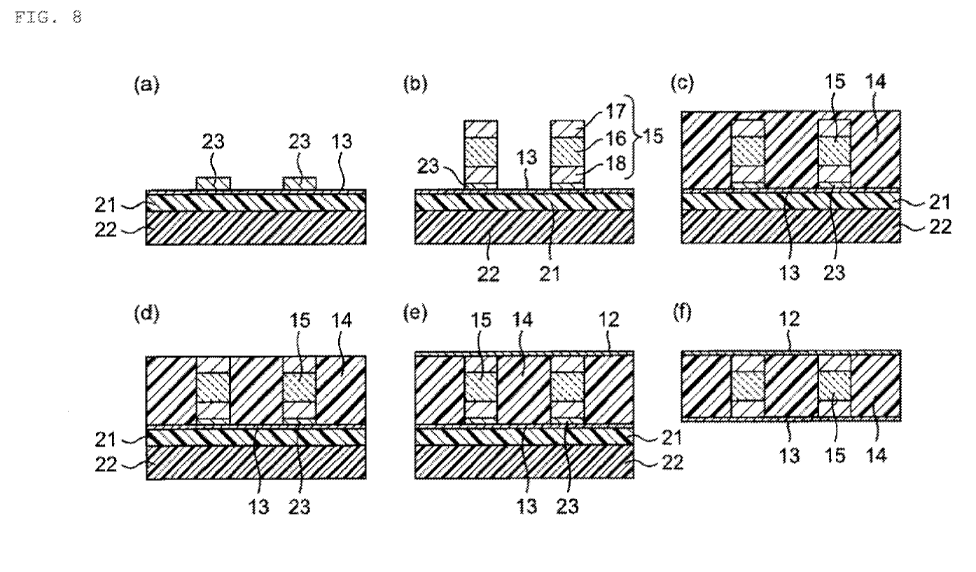

a capacitor 15 is disposed on the adhesive material so as to bring a second capacitor electrode 18 into contact with the adhesive material (FIG. 7),

an insulating material is supplied onto the film so as to fully embed the capacitor 15 in the insulating material (insulating layer 14), and then solidified (step (b) in FIG. 7),

the surface of the insulating layer 14 is polished to expose a first capacitor electrode 17 of the capacitor 15 from the upper surface (surface on the upper side in the drawing) of the insulating layer 14 (step (c) in FIG. 7),

a first metal layer 12 is formed on the upper surface of the insulating layer 14 and the exposed surface of the first capacitor electrode 17 (step (d) in FIG. 7),

the adhesive material 21 and the support film 22 are removed (step (e) in FIG. 7), and

a second metal layer 13 is formed on the lower surface (surface on the lower side in the drawing) of the insulating layer 14 (step (f) in FIG. 7).

The adhesive material 21 is not particularly limited as long as it can be removed later, but a temperature sensitive adhesive material (e.g., Intelimer (registered trademark) tape) is preferable.

The support film 22 is not particularly limited, but a resin film such as a polyethylene terephthalate (PET) film is preferable.

The method for supplying the insulating material for the insulating layer is not particularly limited, and the insulating material is supplied by a dispenser, screen printing, inkjet or the like.

The method for forming the first metal layer 12 and the second metal layer 13 is not particularly limited and, for example, a method such as electrolytic plating, electroless plating, a CVD method, vapor deposition, sputtering or baking of a conductive paste can be used, and electrolytic plating or electroless plating is preferable. Alternatively, a metal foil may be formed separately, and bonded to the insulating layer using an adhesive, for example a conductive adhesive, or by pressure bonding etc.

In another embodiment, a capacitor in-built core insulating film 11 can be manufactured in the following manner:

a support film 22 having a surface coated with an adhesive 21 is provided,

a second metal layer 13 is formed on the adhesive material 21,

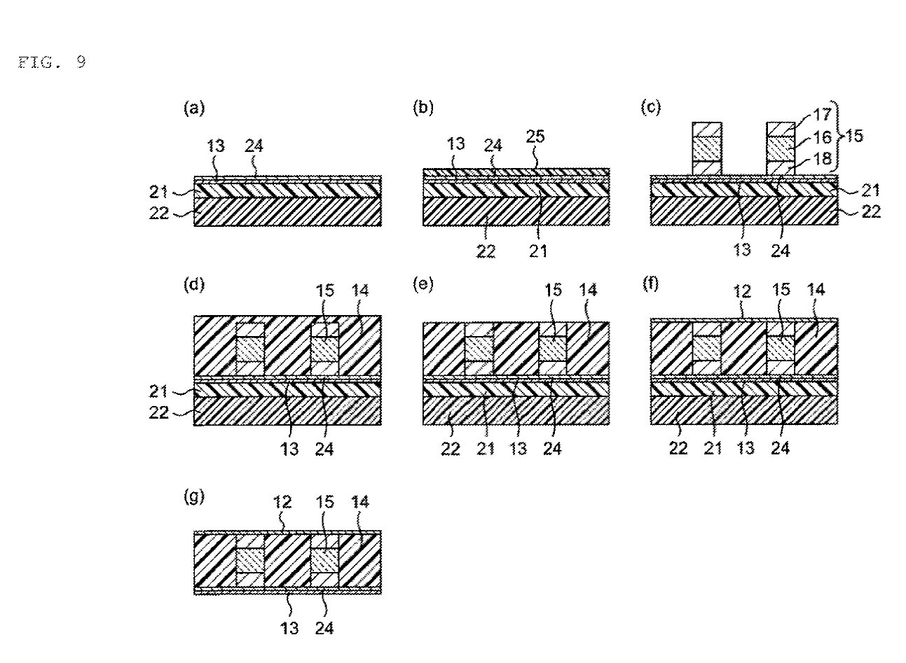

a solder 23 is applied onto the second metal layer 13 (step (a) in FIG. 8),

a capacitor 15 is disposed on the solder 23 so as to bring a second capacitor electrode 18 into contact with the solder 23, and subjected to a reflow treatment (step (b) in FIG. 8),

an insulating material is supplied onto the film so as to fully embed the capacitor 15 in the insulating material (insulating layer 14), and then solidified (step (c) in FIG. 8),

the surface of the insulating layer 14 is polished to expose a first capacitor electrode 17 of the capacitor 15 from the upper surface (surface on the upper side in the drawing) of the insulating layer 14 (FIG. 8(d)),

a first metal layer 12 is formed on the upper surface of the insulating layer 14 and the exposed surface of the first capacitor electrode 17 (FIG. 8(e)), and

the adhesive material 21 and the support film 22 are removed (FIG. 8(f)).

The method for forming the second metal layer 13 on the adhesive material 21 is not particularly limited, and, for example, a method such as electrolytic plating, electroless plating, a CVD method, vapor deposition, sputtering or baking of a conductive paste can be used. Alternatively, a metal foil may be formed separately, and bonded to the insulating layer using a conductive adhesive, or by pressure bonding etc.

The solder material is not particularly limited, and examples thereof include Pb-free solders such as SnAg-based solder, SnCu-based solder, SnSb-based solder and SnBi-based solder, and Pb-containing solders such as Sn-37Pb solder.

In still another aspect, a capacitor built-in core insulating film 11 can be manufactured in the following manner:

a support film 22 having a surface coated with an adhesive 21 is provided,

a second metal layer 13 is formed on the adhesive material 21, and a tin layer (a Sn layer, or an alloy layer of Sn and Ag, Bi, Cu or In) 24 is formed on the second metal layer 13 (step (a) in FIG. 9),

a flux 25 is applied onto the tin layer 24 (step (b) in FIG. 9),

a capacitor 15 is disposed on the flux layer 25 so as to bring a second capacitor electrode 18 into contact with the flux layer 25, and subjected to a reflow treatment (step (c) in FIG. 9),

an insulating material is supplied onto the film so as to fully embed the capacitor 15 in the insulating material (insulating layer 14), and then solidified (step (d) in FIG. 9),

the surface of the insulating layer 14 is polished to expose a first capacitor electrode 17 of the capacitor 15 from the upper surface (surface on the upper side in the drawing) of the insulating layer 14 (step (e) in FIG. 9),

a first metal layer 12 is formed on the upper surface of the insulating layer 14 and the exposed surface of the first capacitor electrode 17 (step (f) in FIG. 9), and

the adhesive material 21 and the support film 22 are removed (step (g) in FIG. 9).

The flux is not particularly limited as long as it is a flux for soldering, and it is preferable to use a rosin-based flux or the like. The method for applying the flux is not particularly limited, and the flux is applied by a dispenser, screen printing, inkjet or the like.

The present invention is also directed to a process for manufacturing a capacitor built-in substrate employing the capacitor built-in insulating films described above. To this end, respective buildup layers 34 are laminated to respective opposed main surfaces of the capacitor built-in core insulating film 11 after the capacitor built-in core insulating film is obtained.

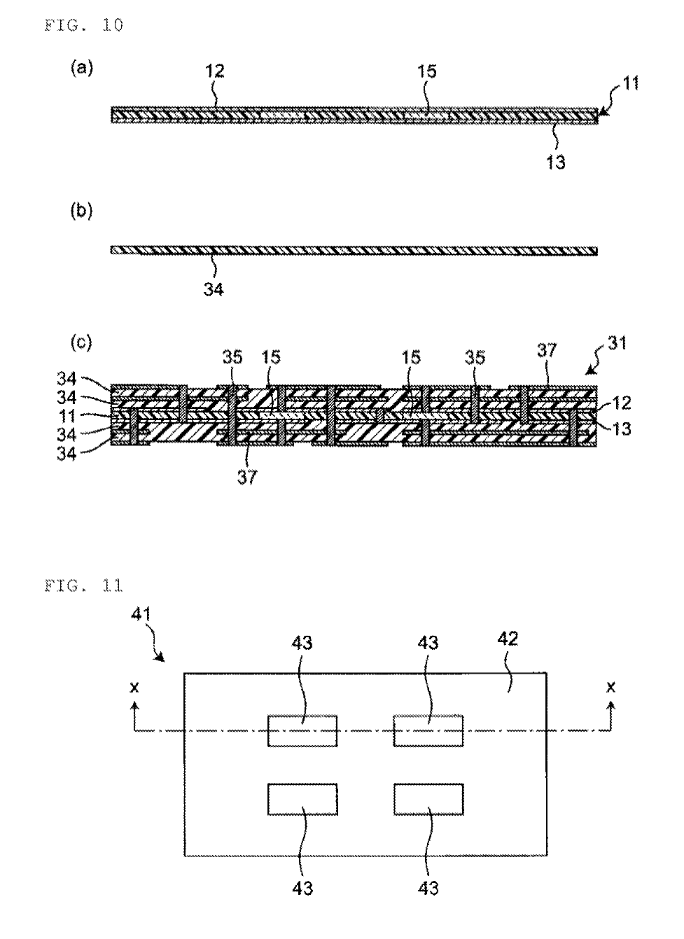

For example, as shown in steps (a) and (b) in FIG. 10, a capacitor built-in core insulating film 11 and two pairs of buildup layers 34 are provided. Respective buildup layers 34 are laminated on respective opposed main surfaces (top and bottom surfaces in FIG. 10) of the capacitor built-in core insulating film 11. A respective second built-up layer 34 is laminated to the foregoing buildup layers as shown in step (c) of FIG. 10. The buildup layers 34 are then thermally solidified, and appropriate via holes are formed by a laser or the like, and the via holes are filled by plating (electrolytic plating or electroless plating) or the like to form vias 35. Wiring patterns 37 are then formed on respective buildup layers 34 by a subtractive method, a semi-additive method or the like. By repeating such a step of laminating a buildup layer, the capacitor built-in substrate 31 of the present invention as shown in step (c) in FIG. 10 can be obtained.

The buildup layers 34 are not particularly limited as long as they have insulation quality, and typical examples thereof include resin substrates such as those of epoxy-based resins, polyimide-based resins and fluorine-based resins. One or more vias for securing conduction to the built-in capacitor may be provided in the buildup layer beforehand.

The number and disposition of the capacitor built-in core insulating films and buildup layers to be used are not limited to the illustrated example and can be appropriately set according to the purpose of the capacitor built-in substrate.

The method for bonding/laminating the capacitor built-in core insulating film(s) and the buildup layer(s) to each other is not particularly limited, and examples thereof include a method using an adhesive, and a method utilizing pressure bonding, typically thermocompression bonding.

After lamination of the capacitor built-in core insulating film(s) and the buildup layer(s), one or more vias for securing conduction with the built-in capacitor or internal wiring may be formed.

Another manufacturing method of the present invention is a method for manufacturing a capacitor built-in substrate, the method including the steps of:

preparing a capacitor built-in interlayer insulating film; and

laminating the capacitor built-in interlayer insulating film as a buildup layer on a core insulating film,

wherein

the capacitor built-in interlayer insulating film includes an insulating layer and a capacitor, and

the capacitor is disposed so as to extend through the insulating layer with a capacitor electrode being exposed from each of two opposed main surfaces of the insulating layer.

First, the capacitor built-in interlayer insulating film will be described.

As shown in FIGS. 11 and 12, a capacitor built-in core insulating film 41 for use in this embodiment schematically includes an insulating layer 42 and a plurality of capacitors 43. The capacitors 43 each include a dielectric layer 44, a first capacitor electrode 45 and a second capacitor electrode 46. The capacitors 43 are disposed so as to extend through the insulating layer 42, with their respective capacitor electrodes (i.e., the first capacitor electrode 45 and the second capacitor electrode 46) being exposed from the insulating layer 42.

As the insulating layer 42 and the built-in capacitor 43, the same insulating layer and capacitor as described in the manufacturing methods described above can be used.

A method for manufacturing a capacitor built-in interlayer insulating film will now be described.

In one embodiment, a capacitor built-in interlayer insulating film 41 can be manufactured in the following manner:

a support film 22 having a surface coated with an adhesive 21 is provided,

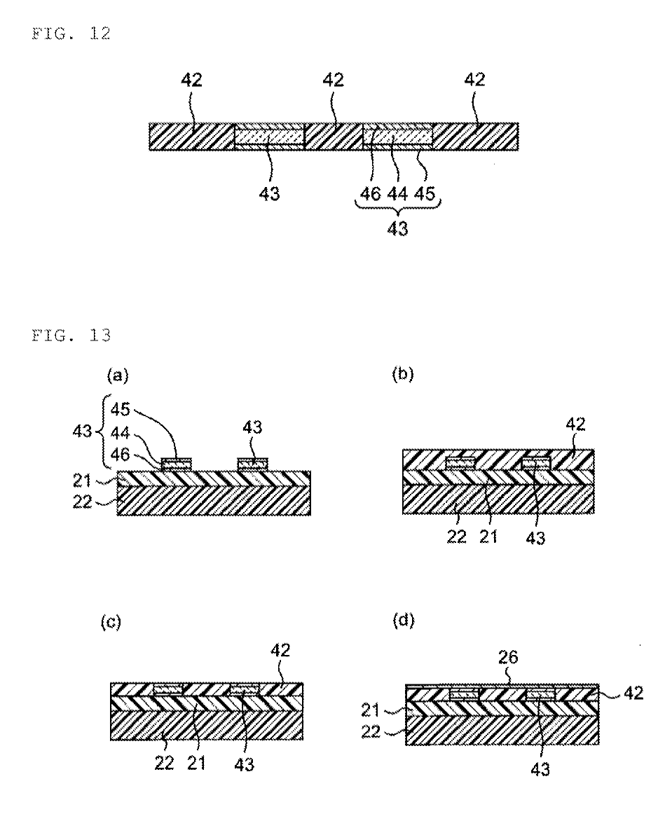

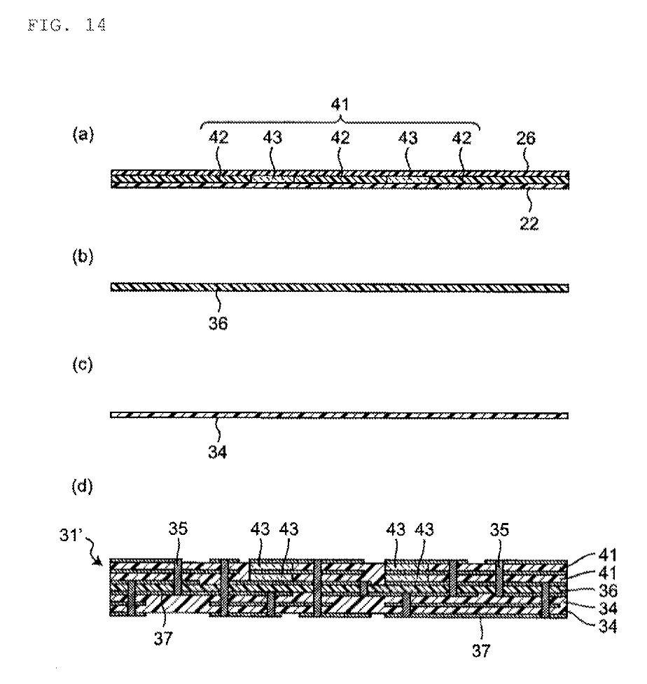

a capacitor 43 is disposed on the adhesive material so as to bring a second capacitor electrode 46 into contact with the adhesive material (step (a) in FIG. 13),

an insulating material is supplied onto the film so as to fully embed the capacitor 43 in the insulating material (insulating layer 42), and then solidified (step (b) in FIG. 13), and

the surface of the insulating layer 42 is polished to expose a first capacitor electrode 45 of the capacitor 43 from the upper surface (surface on the upper side in the drawing) of the insulating layer 42 (step (c) in FIG. 13). If desired, a protecting film 26 may be further formed on the capacitor built-in interlayer insulating film 41 (step (d) in FIG. 13)q. The adhesive material 21, the support film 22 and the protecting film 26 are removed before use.

As the adhesive material 21 and the support film 22, those described in the first manufacturing method can be used.

The protecting film 26 is not particularly limited, but resin films such as polypropylene films, specifically stretched polypropylene (OPP) films are preferable.

In accordance with a second preferred method for manufacturing a capacitor built-in substrate according to the present invention, a capacitor built-in core insulating film having the structure described in FIG. 13 (after removal of adhesive 21 and support film 22) is laminated on the core insulating film after the capacitor built-in interlayer insulating film is obtained. Here, a buildup layer may be further laminated.

For example, as shown in steps (a) and (b) in FIG. 14, a pair of capacitor built-in interlayer insulating films 41, a pair of buildup layers 34 and a core insulating film 36 are provided. Respective wiring patterns 37 are formed on opposed main surfaces of the core insulating film 36 by a subtractive method, a semi-additive method or the like. The capacitor built-in core insulating film 41, from which the support film 22 has been removed, is then laminated on one main surface of the core insulating film, and one of the buildup layers 34 is laminated on the other (opposed) main surface of the core insulating film. In this embodiment a second capacitor built-in interlayer insulating film 41 is laminated onto the first capacitor built-in interlayer insulating film 41 and a second core insulating film 36 is laminated to the first core insulating film 36 as shown in step (d) of FIG. 14. The buildup layers are then solidified, one or more via holes are then formed by a laser or the like, and the via holes are filled by plating (electrolytic plating or electroless plating) or the like to form vias 35 as appropriate. By repeating the lamination step, the capacitor built-in substrate of the present invention as shown in step (d) of FIG. 14 can be obtained.

The number and disposition of capacitor built-in interlayer insulating films and buildup layers to be used are not limited to the illustrated example, and can be appropriately set according to the purpose.

The method for bonding the capacitor built-in interlayer insulating films 41, the core insulating film 36 and the buildup layers 34 to one another is not particularly limited, and examples thereof include a method using an adhesive, and a method utilizing pressure bonding, typically thermocompression bonding.

After lamination of the capacitor built-in interlayer insulating films 41, the core insulating film 36 and the buildup layers 34 and one or more vias for securing conduction with the built-in capacitors or internal wirings may be formed.

The methods of the present invention do not include a step of surface-mounting a capacitor on a substrate, and the substrate manufacturing step and the substrate lamination step can be successively carried out, so that steps in the whole manufacturing are well linked, and the time of the manufacturing steps is shortened. Therefore, it is possible to reduce the cost and improve the quality of products. In addition, according to the second manufacturing method using the capacitor built-in interlayer insulating film, the capacitor can be disposed near the substrate surface, and therefore the wiring length between the capacitor and an IC component mounted on the surface of the capacitor built-in substrate decreases, leading to improvement of the electrical characteristics of electronic devices.

The first method for manufacturing a capacitor built-in substrate and the second method for manufacturing a capacitor built-in substrate are achieved by using a capacitor built-in core insulating film and a capacitor built-in interlayer insulating film, respectively.

Thus, the present invention also provides a capacitor built-in core insulating film including a first metal layer and a second metal layer; an insulating layer; and a capacitor,

wherein

the first metal layer and the second metal layer are disposed so as to face each other with the insulating layer interposed between the first metal layer and the second metal layer, and

the capacitor is disposed so as to extend through the insulating layer, with one capacitor electrode being electrically connected to the first metal layer and the other capacitor electrode being electrically connected to the second metal layer.

The present invention also provides a capacitor built-in interlayer insulating film including an insulating layer; and a capacitor, wherein the capacitor is disposed so as to extend through the insulating layer with a capacitor electrode being exposed from each of both main surfaces of the insulating layer.

The capacitor built-in core insulating film and the capacitor built-in interlayer insulating film are in the form of a thin film, and therefore for improving handling characteristics and durability, a protecting film or a supporting film may be provided on one or both of main surfaces.

Thus, the present invention also provides a film product including:

a capacitor built-in core insulating film including a first metal layer and a second metal layer; an insulating layer; and a capacitor, wherein the first metal layer and the second metal layer are disposed so as to face each other with the insulating layer interposed between the first metal layer and the second metal layer, and the capacitor is disposed so as to extend through the insulating layer, with one capacitor electrode being electrically connected to the first metal layer and the other capacitor electrode being electrically connected to the second metal layer; and

a protecting film or a support film on one or both of main surfaces of the capacitor built-in core insulating film.

The present invention also provides a film product including:

a capacitor built-in interlayer insulating film including an insulating layer; and a capacitor, wherein the capacitor is disposed so as to extend through the insulating layer with a capacitor electrode being exposed from each of both main surfaces of the insulating layer; and

a protecting film or a support film on one or both of main surfaces of the capacitor built-in interlayer insulating film.

The method for manufacturing a capacitor built-in substrate according to the present invention is capable of manufacturing a capacitor built-in substrate at a low cost and in a short time with well linked steps, and therefore can be suitably used in manufacturing of substrates for various electronic devices.

### DESCRIPTION OF REFERENCE SYMBOLS

11: Capacitor built-in core insulating film
12: First metal layer
13: Second metal layer
14: Insulating layer
15: Capacitor
16: Dielectric layer
17: First capacitor electrode
18: Second capacitor electrode
21: Adhesive material
22: Support film
23: Solder
24: Tin layer
25: Flux
26: Protecting film
31, 31′: Capacitor built-in substrate
34: Buildup layer
35: Via
36: Core insulating film
37: Wiring pattern
41: Capacitor built-in interlayer insulating film
42: Insulating layer
43: Capacitor
44: Dielectric layer
45: First capacitor electrode
46: Second capacitor electrode
51: Capacitor
52: High-porosity section
53: Low-porosity section
54: Conductive-porous base material
55: Dielectric layer
56: Upper electrode
57: Wiring electrode
58: Protecting layer
59: First capacitor electrode
60: Second capacitor electrode
71: Capacitor
72: High-porosity section
73: Low-porosity section
74: Conductive-porous base material
75: Dielectric layer
76: Upper electrode
77: Support section
79: First capacitor electrode
80: Second capacitor electrode

1. A method for manufacturing a capacitor built-in substrate, the method comprising:
(a) providing a capacitor built-in core insulating film comprising:
(i) first and second metal layers which face each other with an insulating layer interposed there between; and
(ii) a capacitor located in said insulating layer such that respective first and second capacitor electrodes of each of the capacitors are electrically connected to the first and second metal layers; and
(b) laminating first and second buildup layers to respective opposing main surfaces of the capacitor built-in core insulating film.

2. The method for manufacturing a capacitor built-in substrate of claim 1, wherein the insulating layer has first and second opposed surfaces on which the first and second metal layers are located, respectively.

3. The method for manufacturing a capacitor built-in substrate according to claim 1, wherein the capacitor comprises a conductive porous base material with a dielectric layer situated on the conductive porous base material, and the first capacitor electrode is situated on the dielectric layer.

4. The method for manufacturing a capacitor built-in substrate according to claim 1, wherein a plurality of capacitors are located in the capacitor built-in core insulating film.

5. The method for manufacturing a capacitor built-in substrate according to claim 4, wherein each of the plurality of capacitors have respective first and second capacitor electrodes which are electrically connected to the first and second metal layers, respectively.

6. A method for manufacturing a capacitor built-in substrate, the method comprising:
(a) providing a capacitor built-in interlayer insulating film, comprising:
(i) an insulating layer having first and second main surfaces opposing one another; and
(ii) a capacitor having first and second capacitor electrodes, the capacitor being located in the insulating layer and extending from the first main surface of the insulating layer to the second main surface of the insulating layer with the first capacitor electrode being exposed at the first main surface of the insulating layer and the second capacitor electrode exposed at the second main surface of the insulating layer; and
(b) laminating the capacitor built-in interlayer insulating film on a core insulating film.

7. The method for manufacturing a capacitor built-in substrate according to claim 6, wherein the capacitor includes a conductive porous base material and a dielectric layer situated on the conductive porous base material, and the first conductor electrode is situated on the dielectric layer.

8. The method for manufacturing a capacitor built-in substrate according to claim 6, wherein a plurality of capacitors are located in the capacitor built-in core insulating film.

9. A capacitor built-in core insulating film, comprising
(a) first and second metal layers which face each other with an insulating layer interposed there between; and
(b) a capacitor located in said insulating layer such that respective first and second capacitor electrodes of the capacitor are electrically connected to the first and second metal layers.

10. The capacitor built-in core insulating film of claim 9, wherein the insulating film has first and second opposed surfaces on which the first and second metal layers are respectively located.

11. The capacitor built-in core insulating film according to claim 9, wherein the capacitor includes a conductive porous base material and a dielectric layer situated on the conductive porous base material, and the first capacitor electrode is situated on the dielectric layer.

12. The capacitor built-in core insulating film according to claim 9, wherein a plurality of capacitors are located in the capacitor built-in core insulating film.

13. The capacitor built-in core insulating film according to claim 12, wherein each of the plurality of capacitors have respective first and second capacitor electrodes which are respectively electrically connected to the first and second metal layers.

14. A capacitor built-in interlayer insulating film comprising:
(a) an insulating layer having first and second main surfaces opposing one another; and
(b) a capacitor having first and second capacitor electrodes, the capacitor being located in the insulating layer and extending from the first main surface of the insulating layer to the second main surface of the insulating layer with the first capacitor electrode being exposed at the first main surface of the insulating layer and the second capacitor electrode being exposed at the second main surface of the insulating layer

15. The capacitor built-in interlayer insulating film according to claim 14, wherein the capacitor includes a conductive porous base material and a dielectric layer situated on the conductive porous base material, and the first conductor electrode is situated on the dielectric layer.

16. The capacitor built-in interlayer insulating film according to claim 14, wherein a plurality of capacitors are located in the capacitor built-in core insulating film.

17. The capacitor built-in interlayer insulating film according to claim 14, further comprising a protecting film or a support film on one or both of main surfaces of the capacitor built-in core insulating film.

18. The capacitor built-in interlayer insulating film according to claim 15, further comprising a protecting film or a support film on one or both of main surfaces of the capacitor built-in core insulating film.
